(19) United States
(12) Patent Application Publication
(10) Pub. No.: US 2010/0126854 A1
(43) Pub. Date: May 27, 2010

(54) SPUTTERING TARGET

(75) Inventor: Daniel O. Clark, Pleasanton, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/277,197

(22) Filed: Nov. 24, 2008

(51) Int. Cl. C23C 14/34; C23C 14/00

(52) U.S. Cl. 204/298.12; 118/726

(57) ABSTRACT

Embodiments of the present invention generally include a sputtering target capable of substantially reducing the amount of wasted material associated with conventional sputtering targets. In one embodiment, the sputtering target includes a fluidized bed of sputtering material that constantly maintains a planar sputtering surface throughout the sputtering process. In one embodiment, the fluidized bed of sputtering material is either periodically or constantly supplied with sputtering material to both maintain a planar sputtering surface and reduce downtime of the sputtering equipment.

### BACKGROUND OF THE INVENTION

1. Field of the Invention

Embodiments of the present invention generally relate to a sputtering target for use in physical vapor deposition (PVD) equipment.

2. Description of the Related Art

Typical PVD, or sputtering, equipment includes a vacuum chamber, a target containing the material to be sputtered, a process gas source that provides a process gas to the vacuum chamber, and equipment to generate an electric field. Additionally, a substrate is positioned on a susceptor within the vacuum chamber. The electric field generating equipment is connected to both the susceptor and the target such that an electric field is generated therebetween. In operation, the electric field ionizes the process gas, i.e., the electric filed generates plasma between the target and the susceptor, and accelerates the ionized gas atoms towards the target. As a result, the ionized gas atoms impact the target and dislodge particles from the target material. Once free from the target, these dislodged particles eventually deposit themselves on the substrate as a thin-film.

Magnetron sputtering employs equipment that generates a magnetic field orthogonal to the electric field generated between the target and the susceptor. This magnetic field exploits cycloid motion of electrons within the electric field to increase the plasma density proximate the target. As a result, an increased number of ion generating electrons remain proximate the target, and a greater number of process gas ions impact the target. However, slight nonuniformities in the magnetic field add up over time to create nonuniform erosion of the surface of the target.

FIG. 1 provides a pair of side-by-side cross-sectional views of a typical planar sputtering target 100 designated as ‘before’ 101 and ‘after’ 102. These views 101, 102 illustrate the profile of a target's sputtering surface 105 at the start and end of the target's useful life, respectively. Line 111 represents an axial centerline of the target 100. Line 112 is a reference line for noting differences between the before and after conditions.

At the start of the target's operational life, the target 100 has an essentially planar sputtering surface 113 as seen on the ‘before’ view 101. At or near the end of its useful life, the target 100 has developed a nonplanar sputtering surface 115 characterized by grooves 114, 118 and by peaks 116. Such grooves 118 and peaks 116 tend to undesirably interfere with the edge-to-edge uniformity of deposition rate. At some point, the disparity between the target's grooves 118 and peaks 116 causes too much edge-to-edge variation in the thickness of the film deposited on the substrate, and the eroded target must be replaced.

The length of the commercially useful life of a given target may be cut short by a number of mechanisms including the development of a severely nonuniform erosion profile in the sputtering surface of the target. Of course, any material not consumed from the target is wasted because it is not deposited onto the substrate during the sputtering process. Frequently, as much as 70% of the sputtering material contained in a typical planar sputtering target may be wasted.

Therefore, a need exists for a sputtering target that minimizes the waste associated with conventional planar sputtering targets.

### SUMMARY OF THE INVENTION

In one embodiment of the present invention, a sputtering target comprises a fluidized sputtering medium, a tray member for containing the fluidized sputtering medium, and a leveling member for maintaining a substantially planar sputtering surface on the fluidized sputtering medium.

In one embodiment, a sputtering target comprises a fluidized sputtering medium, a tray member for containing the fluidized sputtering medium, a leveling member for maintaining a planar sputtering surface on the fluidized sputtering medium, and a loading mechanism for replenishing the fluidized sputtering medium as the fluidized sputtering medium is consumed during a sputtering process. In one embodiment the tray member has a plurality of orifices extending therethrough.

In yet another embodiment of the present invention, a sputtering target comprises a fluidized sputtering medium, a tray member for containing the fluidized sputtering medium, a leveling member comprising a vibrational component for maintaining a planar sputtering surface on the fluidized sputtering medium, and a loading mechanism for replenishing the fluidized sputtering medium as the fluidized sputtering medium is consumed during a sputtering process. In one embodiment, the fluidized sputtering medium includes a plurality of spherical pellets of sputtering material. In one embodiment, the tray member has a plurality of orifices extending therethrough. In one embodiment, the orifices are connected to a supply of process gas.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 (Prior Art) is a before and after cross-sectional view demonstrating a typical erosion profile of a planar sputtering target.

FIG. 2 is a schematic cross-sectional view of a planar sputtering target according to one embodiment of the present invention.

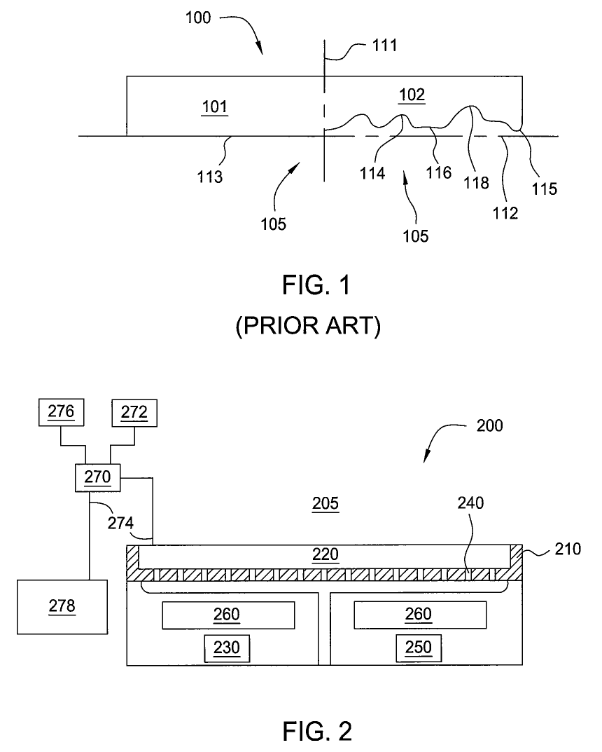

### DETAILED DESCRIPTION

Embodiments of the present invention generally include a sputtering target capable of substantially reducing the amount of wasted material associated with conventional sputtering targets. In one embodiment, the sputtering target includes a fluidized bed of sputtering material that constantly maintains a planar sputtering surface throughout the sputtering process. In one embodiment, the fluidized bed of sputtering material is either periodically or constantly supplied with sputtering material to both maintain a planar sputtering surface and reduce downtime of the sputtering equipment.

FIG. 2 is a schematic cross-sectional view of a planar sputtering target 200 according to one embodiment of the present invention. The sputtering target 200 includes a tray 210 that contains pellets 220 of sputtering material. The pellets 220 of sputtering material may be comprised of any sputtering material known in the art, such as aluminum or molybdenum. In one embodiment, the pellets 220 of sputtering material are formed from material salvaged from spent traditional sputtering targets that have been cut or ground into granules or pellets. In one embodiment, the pellets 220 are spheres of sputtering material. The spheres of sputtering material may have a diameter ranging from about 0.5 mm to about 15 mm. In one embodiment, the spheres are substantially the same size. In one embodiment, the spheres are of varying size.

In one embodiment, the pellets 220 of sputtering material are extruded rods of sputtering material. In one embodiment, the rods of sputtering material have a diameter ranging from about 0.5 mm to about 15 mm. In one embodiment, the rods have a length ranging from about 1 mm to about 25 mm or more. In one embodiment, the rods are substantially the same size. In one embodiment, the rods are of varying size.

In one embodiment of the present invention, the pellets 220 of sputtering material are any of a number of cross-sectional shapes, including triangular, quadrilateral, hexagonal, octagonal or some other polygonal shape. In one embodiment, the pellets 220 of sputtering material are all of substantially the same shape and/or size. In one embodiment, the pellets 220 of sputtering material are of varying shapes and/or sizes to improve electrical and thermal conductivity and packing efficiency. In one embodiment, the pellets 220 of sputtering material are granules of sputtering material having irregular shapes.

In one embodiment, the sputtering target 200 has a leveling mechanism 230. In one embodiment, the leveling mechanism 230 is a mechanical vibration mechanism. The mechanical vibration mechanism constantly or periodically vibrates the tray 210 in order to level the pellets 220 as they are consumed during the sputtering process and keep the sputtering surface of the sputtering target 200 substantially planar.

In one embodiment, the sputtering target 200 includes one or more gas supply orifices 240 connected to a gas supply source (not shown). The gas supply source supplies a process gas, such as argon, through the orifices 240 to the pellets 220 in the tray 210, and into a process area 205. The process gas functions both to level the pellets 220 in the tray 210 as well as to supply process gas for ionization into plasma for sputtering the pellets 220 of sputtering material onto a substrate. In one embodiment, the process gas is a mixture of gasses, such as helium and argon. In one embodiment, the process gas includes oxygen gas. In one embodiment, the process gas includes methane. In one embodiment, the process gas provides cooling or temperature control for the sputtering target 200. In one embodiment, the process gas provides enhanced plasma deposition efficiency.

In one embodiment, the sputtering target 200 includes a cooling means 250 positioned beneath the tray 210. In one embodiment, the cooling means 250 is a volume of coolant that is in contact with a portion of the tray 210. The cooling means 250 prevents overheating of the sputtering target 200.

In one embodiment, the target 200 includes an integrated pattern magnet set 260 positioned beneath the tray 210. In one embodiment, the magnet set 260 may include moving and/or stationary permanent and/or electromagnets. A spacing between the magnet set 260 and the tray 210 may be provided by nonmagnetic shims or other nonmagnetic spacing means. The magnet produces a flux field of a given intensity. At least a portion, if not all, of the produced flux may pass through the target 200 into the process area 205 to ionize the process gas into plasma for sputtering the pellets 220 of sputtering material.

In one embodiment, pellets 220 of sputtering material are added to the tray 210 as the pellets 220 are consumed in the sputtering process via a loading means 270. In one embodiment, loading means 270 includes a sensor 272, a loader 274, and a controller 276.

The sensor 272 senses the loss of target material consumed by the sputtering process. In one embodiment, the sensor 272 is a weight sensor, such as a load cell built into the target 200. In one embodiment, the sensor 272 light sensor, ultrasonic sensor, or radar sensor that senses the loss of volume of the pellets 220 of sputtering material consumed in the sputtering process.

The loader 274 replaces the pellets 220 into the tray 210 as the sputtering material is consumed. In one embodiment, the loader 274 is a screw auger or bucket scoop that transports the pellets 220 from a storage bin 278 to the tray 210 as the sputtering material is consumed.

In one embodiment, the controller 276 is an on-board or central computer that receives signals from the sensor 272 and provides signals to the loader 274 to transfer the pellets 220 of sputtering material from the storage bin 278 to the tray 210 as the sputtering material is consumed.

Therefore, embodiments of the present invention provide a planar sputtering target capable of extended or continuous, which substantially reduces the amount of waste material associated with prior art sputtering targets. Embodiments of the present invention provide a sputtering target with a fluidized bed of sputtering material. The fluidized bed may be continuously leveled to continuously provide a planar sputtering surface. Additionally, the fluidized bed may be continuously renewed with sputtering material as sputtering material is consumed in the sputtering process.

While the foregoing is directed to embodiments of the present invention, other and further embodiments of the invention may be devised without departing from the basic scope thereof, and the scope thereof is determined by the claims that follow.

1. A sputtering target, comprising:
a fluidized sputtering medium;
a tray member for containing the fluidized sputtering medium; and
a leveling member for maintaining a substantially planar sputtering surface on the fluidized sputtering medium.

2. The sputtering target of claim 1, wherein the fluidized sputtering medium comprises a plurality of pellets of sputtering material.

3. The sputtering target of claim 2, wherein one or more of the pellets is in the shape of a sphere.

4. The sputtering target of claim 3, wherein one or more of the pellets is non-spherical in shape.

5. The sputtering target of claim 2, wherein the pellets are spheres of sputtering material having a diameter ranging from about 0.5 mm to about 15 mm.

6. The sputtering target of claim 5, wherein each of the plurality of pellets have substantially the same diameter.

7. The sputtering target of claim 5, wherein the pellets have varying diameters.

8. The sputtering target of claim 2, wherein each of the plurality of pellets are substantially the same size.

9. The sputtering target of claim 2, wherein the pellets are different sizes.

10. The sputtering target of claim 1, wherein the tray has a plurality of orifices therein for supplying a process gas through the fluidized sputtering medium.

11. The sputtering target of claim 10, wherein the leveling member is a mechanical vibration mechanism.

12. A sputtering target, comprising:
a fluidized sputtering medium;
a tray member for containing the fluidized sputtering medium, wherein the tray member has a plurality of orifices extending therethrough for supplying process gas through the fluidized sputtering medium;
a leveling member for maintaining a planar sputtering surface on the fluidized sputtering medium; and
a loading mechanism for replenishing the fluidized sputtering medium as the fluidized sputtering medium is consumed during a sputtering process.

13. The sputtering target of claim 12, wherein the loading mechanism comprises a sensor, a loader, and a controller, wherein the sensor senses the amount of fluidized sputtering medium consumed and the loader replenishes the tray member with additional fluidized sputtering medium.

14. The sputtering target of claim 12, further comprising a cooling device for preventing the sputtering target from overheating during the sputtering process.

15. The sputtering target of claim 12, further comprising a magnet set disposed beneath the tray member.

16. The sputtering target of claim 12, wherein the fluidized sputtering medium comprises a plurality of pellets of sputtering material.

17. A sputtering target, comprising:
a fluidized sputtering medium, wherein the fluidized sputtering medium includes a plurality of spherical pellets of sputtering material;
a tray member for containing the fluidized sputtering medium, wherein the tray member has a plurality of orifices extending therethrough, and wherein the orifices are connected to a supply of process gas;
a leveling member comprising a vibrational component for maintaining a planar sputtering surface on the fluidized sputtering medium; and
a loading mechanism for replenishing the fluidized sputtering medium as the fluidized sputtering medium is consumed during a sputtering process.

18. The sputtering target of claim 17, wherein the spherical pellets have a diameter ranging from about 0.5 mm to about 15 mm.

19. The sputtering target of claim 18, wherein the spherical pellets have substantially equivalent diameters.

20. The sputtering target of claim 18, wherein the spherical pellets have varying diameters.

21. A method of producing a sputtering target, comprising:
providing a tray member with a plurality of orifices formed therethrough;
loading an initial volume of a fluidized sputtering medium into the tray member; and
providing a leveling mechanism in communication with the tray member for maintaining a substantially planar sputtering surface on the fluidized sputtering medium.

22. The method of claim 21, wherein the fluidized sputtering medium comprises a plurality of pellets of sputtering material.

23. The method of claim 22, wherein the pellets are formed from traditional spent sputtering targets.

24. The method of claim 21, further comprising providing a loading mechanism in communication with the tray member for replenishing the fluidized sputtering medium as the fluidized sputtering medium is consumed during a sputtering process.
